(19) United States
(12) Patent Application Publication
(10) Pub. No.: US 2026/0198006 A1
(43) Pub. Date: Jul. 9, 2026

(54) SEMICONDUCTOR DEVICE AND METHOD OF MANUFACTURING THE SEMICONDUCTOR DEVICE

(71) Applicant: SK hynix Inc., Icheon-si Gyeonggi-do (KR)

(72) Inventor: Jae Young OH, Icheon-si Gyeonggi-do (KR)

(73) Assignee: SK hynix Inc., Icheon-si Gyeonggi-do (KR)

(21) Appl. No.: 19/071,390

(22) Filed: Mar. 5, 2025

(30) Foreign Application Priority Data
Jan. 7, 2025 (KR) 10-2025-0002027

(51) Int. Cl. H10B 43/27; H01L 23/00; H01L 25/00; H01L 25/065; H01L 25/18; H10B 41/27; H10B 80/00

(52) U.S. Cl. CPC H10B 43/27; H10B 41/27; H10B 80/00; H10W 90/00; H10W 80/312; H10W 80/327; H10W 90/792

(57) ABSTRACT

A semiconductor device includes at least one channel structure extending through a gate structure, a contact plug extending through a stack, a source structure located on the gate structure to connect to the at least one channel structure, and extending onto the stack, an interlayer insulating layer located on the source structure, a first contact via extending through the interlayer insulating layer and connected to the source structure, and a second contact via including a first portion having a first width in the source structure and connected to the contact plug, and a second portion having a second width and extending through the interlayer insulating layer to connect to the first portion.

### CROSS-REFERENCE TO RELATED APPLICATION

This application claims priority under 35 U.S.C. § 119(a) to Korean Patent Application No. 10-2025-0002027 filed on Jan. 7, 2025, in the Korean Intellectual Property Office, which application is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

The integration degree of a semiconductor device is mainly determined by an area occupied by a unit memory cell. Recently, as improvement in the integration degree of a semiconductor device in which a memory cell is formed as a single layer on a substrate reaches a limit, a three-dimensional semiconductor device in which memory cells are stacked on a substrate is being proposed. In addition, various structures and manufacturing methods are being developed in order to improve operation reliability of the semiconductor device.

### SUMMARY

According to an embodiment of the present disclosure, a semiconductor device may include at least one channel structure extending through a gate structure, a contact plug extending through a stack, a source structure located on the gate structure to connect to the at least one channel structure, and extending onto the stack, an interlayer insulating layer located on the source structure, a first contact via extending through the interlayer insulating layer and connected to the source structure, and a second contact via including a first portion having a first width in the source structure and connected to the contact plug, and a second portion having a second width and extending through the interlayer insulating layer to connect to the first portion.

According to an embodiment of the present disclosure, a semiconductor device may include a gate structure, a stack located at a level corresponding to the gate structure, at least one channel structure extending through the gate structure, a contact plug extending through the gate structure, a source structure located on the gate structure to connect to the at least one channel structure, and extending onto the stack, an interlayer insulating layer located on the source structure, a first contact via extending through the interlayer insulating layer and connected to the source structure, and a second contact via including a first portion having a first width in the source structure and connected to the contact plug, and a second portion having a second width less than the first width and extending through the interlayer insulating layer to connect to the first portion.

According to an embodiment of the present disclosure, a semiconductor device may include a gate structure, a stack located at a level corresponding to the gate structure, a source structure located on the gate structure and extending onto the stack, a contact plug extending into the source structure through the stack, an interlayer insulating layer located on the source structure, a first contact via extending through the interlayer insulating layer and connected to the source structure, a second contact via extending through the interlayer insulating layer into the source structure and connected to the contact plug, a first insulating spacer surrounding a sidewall of the first contact via, and a second insulating spacer surrounding a sidewall of the second contact via and extending between the second contact via and the contact plug.

According to an embodiment of the present disclosure, a method of manufacturing a semiconductor device may include forming a stack on a substrate, forming at least one channel structure extending into the substrate through the stack, forming a contact plug extending into the substrate through the stack, exposing the at least one channel structure and the contact plug by removing the substrate, forming a source structure on the at least one channel structure and the contact plug, forming a first via hole exposing the source structure at a position corresponding to the at least one channel structure, forming a second via hole exposing the source structure at a position corresponding to the contact plug, exposing the contact plug by expanding the second via hole in the source structure, forming a first contact via in the first via hole, and forming a second contact via in the second via hole.

According to an embodiment of the present disclosure, a method of manufacturing a semiconductor device may include forming a peripheral circuit wafer including a peripheral circuit and first bonding pads formed on the peripheral circuit, forming a cell wafer including a gate structure, at least one channel structure extending through the gate structure, a stack, a contact plug extending through the stack, and second bonding pads, bonding the peripheral circuit wafer and the cell wafer so that the first bonding pads and the second bonding pads are connected, forming a source structure on the at least one channel structure and the contact plug, forming a first via hole exposing the source structure at a position corresponding to the at least one channel structure, forming a second via hole exposing the source structure at a position corresponding to the contact plug and having a width greater than a width of the first via hole, forming a first contact via in the first via hole, and forming a second contact via connected to the contact plug in the second via hole.

### BRIEF DESCRIPTION OF THE DRAWINGS

FIGS. 1A and 1B are drawings illustrating a semiconductor device according to an embodiment of the present disclosure.

FIGS. 2, 3, 4, 5, 6, 7, 8, and 9 are drawings illustrating a method of manufacturing a semiconductor device according to an embodiment of the present disclosure.

### DETAILED DESCRIPTION

An embodiment of the present disclosure provides a semiconductor device and a method of manufacturing the semiconductor device having a stable structure and an improved characteristic.

According to an embodiment of the present technology, a semiconductor device having a stable structure and improved reliability may be provided.

Hereinafter, embodiments according to the technical spirit of the present disclosure are described with reference to the accompanying drawings.

Terms such as “first” and “second” are used to distinguish between various elements and do not imply size, order, priority, quantity, or importance of the elements. For example, a first element may be named as a second element in one example, and the second element may be named as a first element in another example. Terms such as “vertical,” “horizontal,” “over,” “side,” “lower,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout.

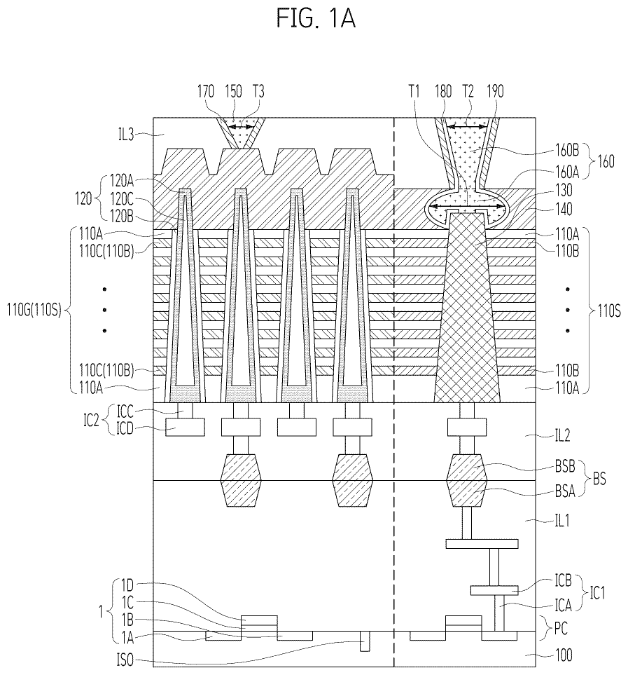

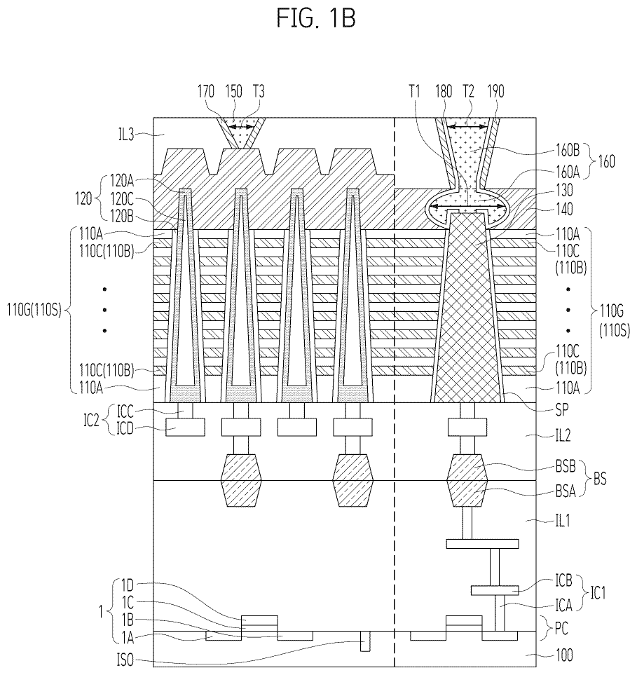

FIGS. 1A and 1B are drawings illustrating a semiconductor device according to an embodiment of the present disclosure.

Referring to FIGS. 1A and 1B, the semiconductor device may include a stack 110S, a gate structure 110G, channel structures 120, a contact plug 130, a source structure 140, a first contact via 150, and a second contact via 160. The semiconductor device may further include a substrate 100, a peripheral circuit PC, an element isolation layer ISO, a first interconnection structure IC1, a second interconnection structure IC2, a bonding structure BS, a first interlayer insulating layer IL1, a second interlayer insulating layer IL2, a third interlayer insulating layer IL3, a first insulating spacer 170, a second insulating spacer 180, a third insulating spacer 190, and an additional insulating spacer SP.

The peripheral circuit PC may be located on the substrate 100. The peripheral circuit PC may include a transistor 1, a capacitor, and the like. The transistor 1 may include junctions 1A and 1B, a gate electrode 1D, and a gate insulating layer 1C. Here, the gate insulating layer 1C may be located between the gate electrode 1D and the substrate 100. The element isolation layer ISO may be located in the substrate 100, an active area may be defined by the element isolation layer ISO, and the transistor 1 may be located in the active area.

The first interconnection structure IC1 may be located on the peripheral circuit PC. The first interconnection structure IC1 may be located in the first interlayer insulating layer IL1. Here, the first interlayer insulating layer IL1 may be located on the substrate 100. The first interconnection structure IC1 may include first vias ICA and first lines ICB.

The first interconnection structure IC1 may be connected to the peripheral circuit PC. For example, at least one of the first vias ICA may be connected to the transistor 1. At least one of the first vias ICA may interconnect the first lines ICB. The first lines ICB may interconnect the first vias ICA. The first interconnection structure IC may include a conductive material such as tungsten. The first interlayer insulating layer IL may include an insulating material such as oxide.

The bonding structures BS may be located on the first interconnection structure IC1. The bonding structure BS may include a first bonding pad BSA and a second bonding pad BSB. The first bonding pad BSA may be located in the first interlayer insulating layer IL1. The second bonding pad BSB may be located in the second interlayer insulating layer IL2. Here, the second interlayer insulating layer IL2 may be located on the first interlayer insulating layer IL1. The bonding structure BS may include a conductive material such as copper.

The second interconnection structure IC2 may be located on the bonding structure BS. The second interconnection structure IC2 may be located in the second interlayer insulating layer IL2. The second interconnection structure IC2 may include second vias ICC and second lines ICD.

The gate structure 110G may be located on the second interconnection structure IC2. The gate structure 110G may include first insulating layers 110A and conductive layers 110B alternately stacked. The conductive layers 110B may be a gate line such as a source selection line, a word line, and a drain selection line. A source selection transistor, a memory cell, or a drain selection transistor may be located in an area where the channel structures 120 and the conductive layers 110B intersect. For example, at least one source selection transistor, a plurality of memory cells, and at least one drain selection transistor stacked along the channel structure 120 may configure one memory string. The conductive layers 110B may include a conductive material such as tungsten, molybdenum, or polysilicon. The first insulating layers 110A may include an insulating material such as oxide.

The stack 110S may be located at a level corresponding to the gate structure 110G. The stack 110S may include first insulating layers 110A and second insulating layers 110B alternately stacked. Here, the second insulating layers 110B may include an insulating material such as oxide.

The channel structures 120 may extend through the gate structure 110G. Each of the channel structures 120 may include a channel layer 120A and a memory layer 120B surrounding the channel layer 120A. Each of the channel structures 120 may further include an insulating core 120C in the channel layer 120A.

The contact plug 130 may extend through the stack 110S. The contact plug 130 may be electrically connected to the peripheral circuit PC. For example, the contact plug 130 may be electrically connected to the peripheral circuit PC through the second interconnection structure IC2, the bonding structure BS, and the first interconnection structure IC1. The contact plug 130 may include an insulating material such as tungsten.

Referring to FIG. 1B, the contact plug 130 may extend through the gate structure 110G. In other words, the contact plug 130 may extend through the stack 110S or the gate structure 110G. The additional insulating spacer SP may surround a sidewall of the contact plug 130. For example, the additional insulating spacer SP may surround the sidewall of the contact plug 130 in the gate structure 110G. In this case, in an embodiment, the additional insulating spacer SP may prevent or mitigate the contact plug 130 and the conductive layers 110C of the gate structure 110G from being electrically connected. Here, the additional insulating spacer SP may include an insulating material such as oxide.

For reference, in this drawing, heights of the channel structures 120 and the contact plug 130 are different, but the heights of the channel structures 120 and the contact plug 130 may be substantially the same.

The source structure 140 may be located on the gate structure 110G. For example, the source structure 140 may be located on the gate structure 110G and may extend to the stack 110S. In other words, the source structure 140 may also exist in an area corresponding to the channel structures 120 and may also exist in an area corresponding to the contact plug 130. The source structure 140 may be connected to the channel structures 120. For example, the source structure 140 may be connected to the channel layers 120A of the channel structures 120.

For reference, in this drawing, an upper surface of the source structure 140 has a shape corresponding to a profile of the channel structures 120, but the upper surface of the source structure 140 may be flat. In addition, in this drawing, a height of the source structure 140 in an area corresponding to the channel structures 120 and a height of the source structure 140 in an area corresponding to the contact plug 130 are different, but the height of the source structure 140 may be constant regardless of an area.

The first contact via 150 may extend through the third interlayer insulating layer IL3. For example, the first contact via 150 may extend through the third interlayer insulating layer IL3 and may be connected to the source structure 140. Here, the third interlayer insulating layer IL3 may be located on the source structure 140. The third interlayer insulating layer IL3 may include an insulating material such as oxide. The first contact via 150 may include a conductive material such as tungsten.

The second contact via 160 may include a first portion 160A and a second portion 160B connected to the first portion 160A. Here, the first portion 160A may extend through the source structure 140. In addition, the first portion 160A may be connected to the contact plug 130. The second portion 160B may extend through the third interlayer insulating layer IL3. The first portion 160A may include a curved surface on a sidewall in the source structure 140. For example, the sidewall of the first portion 160A may include an ellipse shape. However, the present disclosure is not limited thereto, and the sidewall of the first portion 160A may include a circle shape or the like. The first portion 160A may have a first width T1, and the second portion 160B may have a second width T2 different from the first width T1. The first width T1 may be greater than the second width T2. Here, the first width T1 may mean a maximum width in the first portion 160A, and the second width T2 may mean a maximum width of the second portion 160B. For example, the first width T1 may mean a maximum width passing through a center point in the ellipse shape of the first portion 160A, and the second width T2 may mean a width of an upper surface of the second portion 160B.

the first contact via 150 may have a third width T3. The third width T3 may mean a width of an upper surface of the first contact via 150. The third width T3 may be less than the second width T2 of the second contact via 160. For example, the width of the upper surface of the first contact via 150 may be less than the second width T2 of the second portion 160B. The second contact via 160 may include a conductive material such as tungsten.

The first insulating spacer 170 may surround a sidewall of the first contact via 150. For example, the first insulating spacer 170 may surround the sidewall of the first contact via 150 in the third interlayer insulating layer IL3.

The second insulating spacer 180 may surround a sidewall of the second contact via 160. For example, the second insulating spacer 180 may surround the sidewall of the second contact via 160 in the third interlayer insulating layer IL3 and the source structure 140. In other words, the second insulating spacer 180 may surround the sidewall of the second contact via 160 along a profile of the second contact via 160.

In addition, the second insulating spacer 180 may extend between the second contact via 160 and the contact plug 130. For example, the second insulating spacer 180 may extend between the second contact via 160 and the contact plug 130 in the source structure 140. In other words, the second insulating spacer 180 may insulate the source structure 140 and the second contact via 160, and may insulate the source structure 140 and the contact plug 130.

The third insulating spacer 190 may surround a sidewall of the second insulating spacer 180. For example, the third insulating spacer 190 may surround the sidewall of the second insulating spacer 180 in the third interlayer insulating layer IL3.

The first insulating spacer 170 and the third insulating spacer 190 may include substantially the same material. This is because the first and third insulating spacers 170 and 190 may be simultaneously formed in a process of manufacturing a semiconductor device. For example, the first and third insulating spacers 170 and 190 may include an insulating material such as oxide. The first and third insulating spacers 170 and 190 may include SiO₂. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

The second insulating spacer 180 may include a material substantially equal to a material of the first and third insulating spacers 170 and 190, or may include a material different from the material of the first and third insulating spacers 170 and 190. For example, the second insulating spacer 180 may include the material substantially equal to the material of the first and third insulating spacers 170 and 190. The second insulating spacer 180 may include an insulating material such as oxide, and may include SiO₂. In this case, an interface between the second insulating spacer 180 and the third insulating spacer 190 might not exist.

According to the structure described above, the source structure 140 may be located on the gate structure 110G and may extend onto the stack 110S. The second contact via 160 may include the first portion 160A extending through the source structure 140, and the first portion 160A may be connected to the contact plug 130. The second insulating spacer 180 may surround the sidewall of the second contact via 160. In addition, the second insulating spacer 180 may extend between the second contact via 160 and the contact plug 130 in the source structure 140. In this case, in an embodiment, the second insulating spacer 180 may prevent or mitigate an electrical connection between the source structure 140 and the second contact via 160, and may prevent or mitigate an electrical connection between the source structure 140 and the contact plug 130.

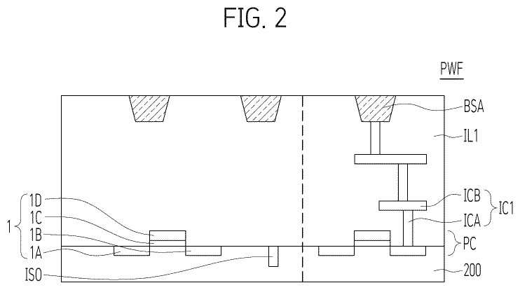

FIGS. 2 to 9 are drawings illustrating a method of manufacturing a semiconductor device according to an embodiment of the present disclosure. Hereinafter, a content overlapping the content described above is omitted.

Referring to FIG. 2, a peripheral circuit wafer PWF may be formed. For example, the peripheral circuit wafer PWF including a peripheral circuit PC and first bonding pads BSA formed on the peripheral circuit PC may be formed.

First, the peripheral circuit PC may be formed on a peripheral circuit substrate 200. The peripheral circuit PC may include a transistor 1, a capacitor, and the like. The transistor 1 may include junctions 1A and 1B, a gate electrode 1D, and a gate insulating layer 1C. Here, the gate insulating layer 1C may be located between the gate electrode 1D and the substrate 100. An element isolation layer ISO may be located in the peripheral circuit substrate 200, an active area may be defined by the element isolation layer ISO, and the transistor 1 may be located in the active area.

Subsequently, a first interconnection structure IC1 may be formed on the peripheral circuit PC. The first interconnection structure IC1 may be formed in a first interlayer insulating layer IL1. Here, the first interlayer insulating layer IL1 may be formed on the peripheral circuit substrate 200. The first interconnection structure IC1 may include first vias ICA and first lines ICB.

The first interconnection structure IC1 may be connected to the peripheral circuit PC. For example, at least one of the first vias ICA may be connected to the transistor 1. At least one of the first vias ICA may interconnect the first lines ICB. The first lines ICB may interconnect the first vias ICA. The first interconnection structure IC1 may include a conductive material such as tungsten. The first interlayer insulating layer IL1 may include an insulating material such as oxide.

Subsequently, the first bonding pads BSA may be formed on the first interconnection structure IC1. Here, the first bonding pads BSA may be formed in the first interlayer insulating layer IL1. The first bonding pads BSA may include a conductive material such as copper

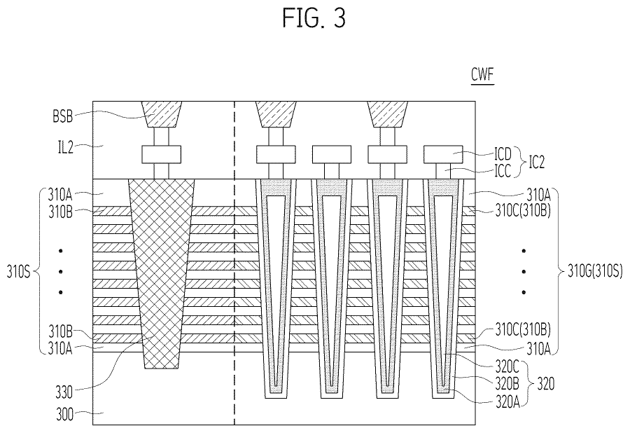

Referring to FIG. 3, a cell wafer CWF may be formed. For example, the cell wafer CWF including a gate structure 310G, channel structures 320 extending through the gate structure 310G, a stack 310S, a contact plug 330 extending through the stack 310S, and second bonding pads BSB may be formed.

First, the stack 310S may be formed on a cell substrate 300. For example, first material layers 310A and second material layers 310B may be alternately stacked on the cell substrate 300 to form the stack 310S. Here, the first material layers 310A may include an insulating material such as oxide, and the second material layers 310B may include a sacrificial material such as nitride.

Subsequently, the channel structures 320 extending through the stack 310S may be formed. For example, the channel structures 320 extending into the cell substrate 300 through the stack 310S may be formed. Each of the channel structures 320 may include a channel layer 320A and a memory layer 320B surrounding the channel layer 320A. The channel structures 320 may further include an insulating core 320C in the channel layer 320A.

The contact plug 330 extending through the stack 310S may be formed. For example, the contact plug 330 extending into the cell substrate 300 through the stack 310S may be formed. Here, the contact plug 330 may include a conductive material such as tungsten.

For reference, in this drawing, heights of the channel structures 320 and the contact plugs 330 are formed differently, the heights of the channel structures 320 and the contact plugs 330 may be substantially equally formed.

Subsequently, a slit extending through the stack 310S may be formed. For example, the slit having a line shape on a plane and extending through the stack 310S may be formed. Here, the slit may be formed as a single trench in a line shape. However, the present disclosure is not limited thereto, and the slit may be formed in a line shape by overlapping a plurality of holes. Subsequently, the second material layers 310B of the stack 310S may be replaced with third material layers 310C through the slit. Accordingly, a gate structure 310G including the first material layers 310B and the third material layers 310C alternately stacked may be formed. Here, the third material layer 310C may be a gate line such as a source selection line, a word line, and a drain selection line as a conductive layer.

A portion of the second material layers 310B may remain without being replaced with the third material layers 310C. In other words, a portion of the stacks 310S may remain without being replaced with the gate structure 310G. For example, the stack 310S of an area where the contact plug 330 is formed may remain without being replaced with the gate structure 310G. However, the present disclosure is not limited thereto, and the stack 310S of the area where the contact plug 330 is formed may also be replaced with the gate structure 310G. In this case, after forming an additional insulating spacer in the stack 310S, the contact plug 330 may be formed. Here, in an embodiment, the additional insulating spacer may prevent or mitigate the third material layers 310C of the gate structure 310G and the contact plug 330 from being electrically connected. Subsequently, a slit structure may be formed in the slit.

For reference, when the second material layers 310B include a conductive material, a process of replacing the second material layers 310B with the third material layers 310C may be omitted. In this case, the stack 310S may be used as the gate structure 310G.

Subsequently, a second interconnection structure IC2 may be formed on the stack 310S and the gate structure 310G. The second interconnection structure IC2 may be formed in a second interlayer insulating layer IL2. Here, the second interlayer insulating layer IL2 may be formed on the stack 310S and the gate structure 310G. The second interconnection structure IC2 may include second vias ICC and second lines ICD.

The second interconnection structure IC2 may be connected to the channel structures 320 and/or the contact plugs 330. For example, at least one of the second vias ICC may be connected to the channel structure 320 or the contact plug 330. At least one of the second vias ICC may interconnect the second lines ICD. The second lines ICD may interconnect the second vias ICC. The second interconnection structure IC2 may include a conductive material such as tungsten. The second interlayer insulating layer IL2 may include an insulating material such as oxide.

Subsequently, the second bonding pads BSB may be formed on the second interconnection structure IC2. Here, the second bonding pads BSB may be formed in the second interlayer insulating layer IL2. The second bonding pads BSB may include a conductive material such as copper.

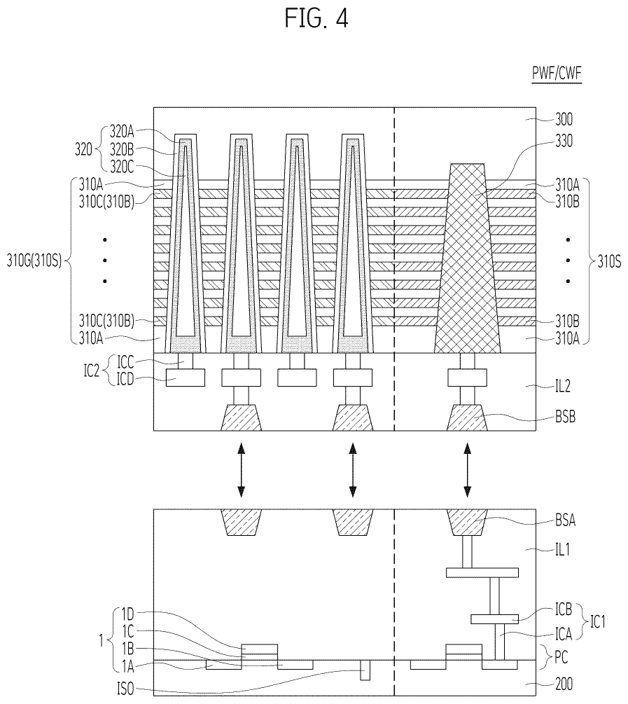

Referring to FIG. 4, the peripheral circuit wafer PWF and the cell wafer CWF may be bonded. For example, the peripheral circuit wafer PWF and the cell wafer CWF may be bonded so that the first bonding pads BSA and the second bonding pads BSB are connected. Accordingly, the contact plug 330 may be electrically connected to the peripheral circuit PC through the second interconnection structure IC2, the second bonding pads BSB, the first bonding pads BSA, and the first interconnection structure IC1.

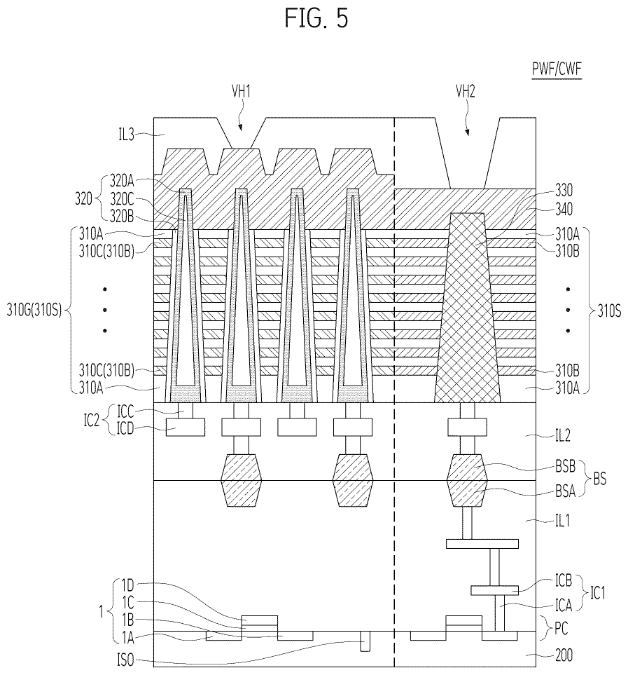

Referring to FIG. 5, the cell substrate 300 may be removed. For example, the cell substrate 300 may be removed so that the channel structures 320 and the contact plug 330 are exposed. Subsequently, the memory layers 320B of the channel structures 320 may be partially removed so that the channel layers 320A of the channel structures 320 are exposed.

Subsequently, a source structure 340 may be formed on the gate structure 310G and the stack 310S. For example, the source structure 340 may be formed on the channel structures 320 and the contact plug 330. Here, the channel layers 320A of the channel structures 320 and the source structure 340 may be connected.

For reference, in this drawing, the source structure 340 is formed along a profile of the channel structures 320, but is not limited thereto. For example, the source structure 340 may be formed so that a height in an area corresponding to the channel structures 320 and a height in an area corresponding to the contact plug 330 are constant.

Subsequently, a third interlayer insulating layer IL3 may be formed on the source structure 340. Here, the third interlayer insulating layer IL3 may include an insulating material such as oxide.

Subsequently, a first via hole VH1 exposing the source structure 340 may be formed at a position corresponding to the channel structures 320. For example, the third interlayer insulating layer IL3 may be etched to form the first via hole VH1 exposing the source structure 340.

A second via hole VH2 exposing the source structure 340 may be formed at a position corresponding to the contact plug 330. For example, the third interlayer insulating layer IL3 may be etched to form the second via hole VH2 exposing the source structure 340.

When the first via hole VH1 is formed, the second via hole VH2 may be formed. However, the present disclosure is not limited thereto, and the second via hole VH2 may be formed after the first via hole VH1 is formed. A width of the second via hole VH2 may be greater than a width of the first via hole VH1. Here, the widths of the first and second via holes VH1 and VH2 may mean widths at substantially the same level. For example, the width of the second via hole VH2 may be greater than the width of the first via hole VH1 at substantially the same level as an upper surface of the third interlayer insulating layer IL3.

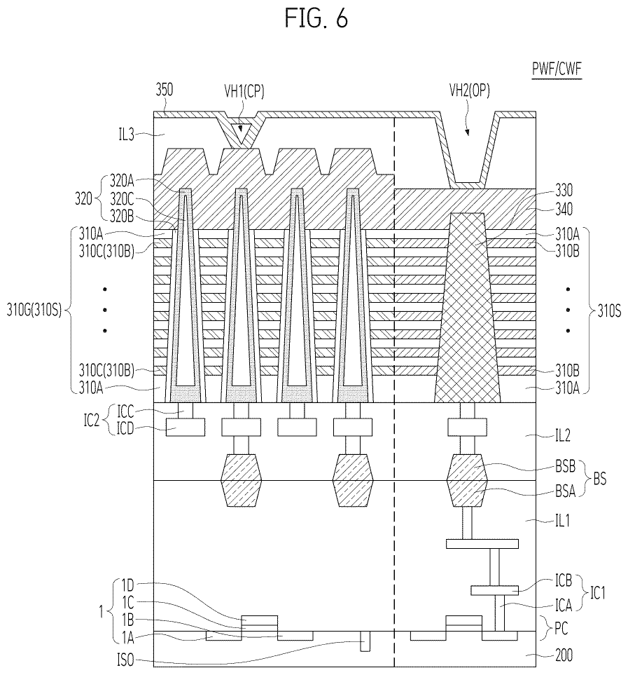

Referring to FIG. 6, a preliminary first insulating spacer 350 may be formed in the first via hole VH1 and the second via hole VH2. For example, the preliminary first insulating spacer 350 may be deposited so that the first via hole VH1 is in a closed state CP and the second via hole VH2 is in an opened state OP. Here, because the first via hole VH1 has the width relatively less than the width of the second via hole VH2, the first via hole VH1 may be in the closed state CP in a process of depositing the preliminary first insulating spacer 350, and because the second via hole VH2 has the width relatively greater than the width of the first via hole VH1, the second via hole VH2 may maintain the opened state OP in the process of depositing the preliminary first insulating spacer 350. The preliminary first insulating spacer 350 may include an insulating material such as oxide. For example, the preliminary first insulating spacer 350 may include SiO₂.

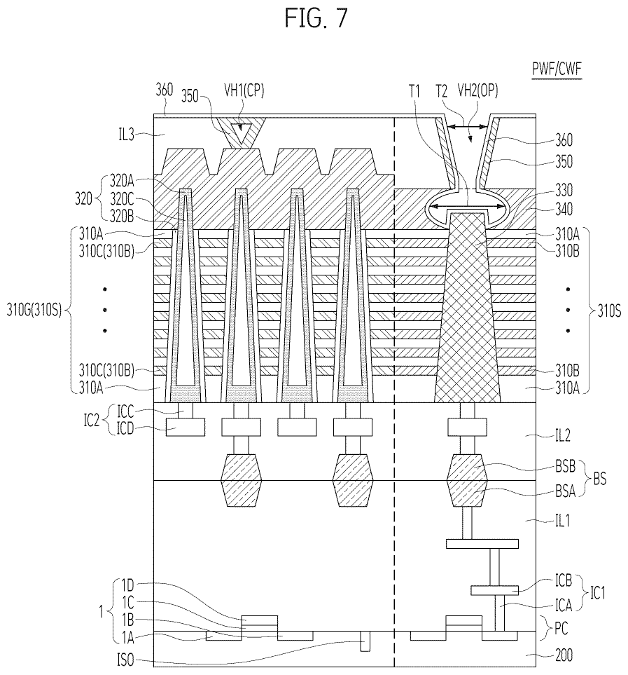

Referring to FIG. 7, the preliminary first insulating spacer 350 may be etched so that the third interlayer insulating layer IL3 is exposed. For example, the preliminary first insulating spacer 350 may be etched so that the closed state CP of the first via hole VH1 is maintained. In this process, a lower surface of the preliminary first insulating spacer 350 formed in the second via hole VH2 may be etched to expose the source structure 340. Here, the preliminary first insulating spacer 350 remaining in the second via hole VH2 may be defined as a third insulating spacer. For reference, the third interlayer insulating layer IL3 may be partially etched in a process of etching the preliminary first insulating spacer 350.

Subsequently, the second via hole VH2 may be expanded in the source structure 340. For example, the second via hole VH2 may be expanded in the source structure 340 so that the contact plug 330 is exposed. The second via hole VH2 may be expanded by removing the source structure 340 by isotropic etching. Here, a side surface of the expanded second via hole VH2 may have a curved shape. For example, the side surface of an expanded portion of the second via hole VH2 may include an ellipse shape. For example, the side surface of an expanded portion of the second via hole VH2 may include an ellipse shape as shown in FIG. 7. However, the present disclosure is not limited thereto, and the side surface of the expanded portion of the second via hole VH2 may include a circle shape or the like. The expanded portion of the second via hole VH2 may have a first width T1, and the second via hole VH2 before expansion may have a second width T2 different from the first width T1. The first width T1 may be greater than the second width T2. Here, the first and second widths T1 and T2 may mean maximum widths. For example, the first width T1 may mean a maximum width passing through a center point in the ellipse shape of the expanded portion of the second via hole VH2, and the second width T2 may mean a maximum width at a level corresponding to an upper surface of the third interlayer insulating layer IL3 of the second via hole VH2 before expansion.

Subsequently, a preliminary second insulating spacer 360 may be formed in the second via hole VH2. For example, the preliminary second insulating spacer 360 may be formed along the contact plug 330 exposed through the expanded second via hole VH2. In an embodiment, the preliminary second insulating spacer 360 may prevent or mitigate the source structure 340 and the contact plug 330 from being electrically connected. Here, because the first via hole VH1 is in the closed state CP, the preliminary second insulating spacer 360 might not be formed in the first via hole VH1. The preliminary second insulating spacer 360 may include an insulating material such as oxide. For example, the preliminary second insulating spacer 360 may include SiO₂.

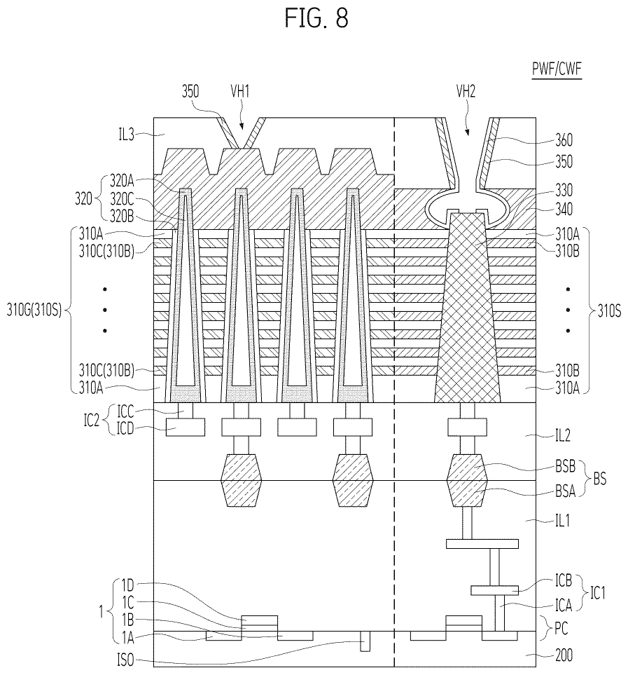

Referring to FIG. 8, the preliminary second insulating spacer 360 may be etched so that the third interlayer insulating layer IL3 is exposed. For reference, the third interlayer insulating layer IL3 and the preliminary first insulating spacer 350 may be partially etched in a process of etching the preliminary second insulating spacer 360.

Subsequently, a lower surface of the preliminary first insulating spacer 350 formed in the first via hole VH1 may be etched to expose the source structure 340. Here, the preliminary first insulating spacer 350 remaining in the first via hole VH1 may be defined as a first insulating spacer.

A lower surface of the preliminary second insulating spacer 360 formed in the second via hole VH2 may be etched to expose the contact plug 330. For example, when the lower surface of the preliminary first insulating spacer 350 formed in the first via hole VH1 is etched, the lower surface of the preliminary second insulating spacer 360 formed in the second via hole VH2 may be etched. Here, the lower surface of the preliminary second insulating spacer 360 may mean a portion contacting an upper surface of the contact plug 330. The preliminary second insulating spacer 360 remaining in the second via hole VH2 may be defined as a second insulating spacer.

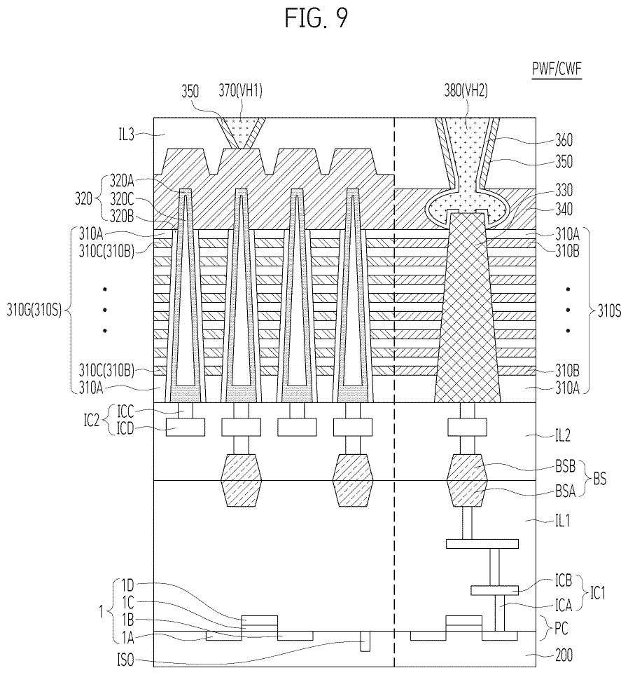

Referring to FIG. 9, a conductive material may be formed in the first via hole VH1 and the second via hole VH2. For example, the conductive material may be formed to fill the first via hole VH1 and the second via hole VH2. Subsequently, the conductive material formed in the first via hole VH1 and the second via hole VH2 may be planarized and removed so that the third interlayer insulating layer IL3 is exposed. Accordingly, a first contact via 370 may be formed in the first via hole VH1, and a second contact via 380 may be formed in the second via hole VH2. In other words, when the first contact via 370 is formed, the second contact via 380 may be formed. Here, the conductive material may include tungsten or the like.

According to the conventional technology, in order to form a contact via connected to a contact plug, a source structure formed at a position corresponding to the contact plug is removed. In other words, in order to remove the source structure formed at a position corresponding to the contact plug, a hard mask is formed, and then the source structure is removed through an etching process. In this case, in an embodiment, the hard mask for removing the source structure is required to be separately manufactured, an etching process is additionally performed, and thus a manufacturing cost of a semiconductor device is increased.

According to an embodiment of the present disclosure, the source structure 340 formed at a location corresponding to the contact plug 330 is not removed. For example, after expanding the second via hole VH2 exposing the contact plug 330 in the source structure 340, the second contact via 380 connected to the contact plug 330 is formed in the second via hole VH2. Here, in an embodiment, the preliminary second insulating spacer 360 is first formed in the second via hole VH2 to prevent or mitigate the source structure 340 and the second contact via 380 from being electrically connected, and to prevent or mitigate the source structure 340 and the contact plug 330 from being electrically connected. In this case, a hard mask for removing the source structure 340 is not required to separately manufacture, and an etching process for removing the source structure 340 is not performed. Therefore, according to an embodiment of the present disclosure, a manufacturing cost of the semiconductor device may be reduced compared to the conventional technology.

According to an embodiment of the manufacturing method described above, the widths of the first via hole VH1 formed at a position corresponding to the channel structures 320 and the second via hole VH2 formed at a position corresponding to the contact plug 330 may be differently formed. By differently forming the widths of the first and second via holes VH1 and VH2, the second via hole VH2 may be selectively expanded in the source structure 340, and the second contact via 380 connected to the contact plug 330 may be formed in the second via hole VH2. Here, in an embodiment, in order to prevent or mitigate the source structure 340 from being electrically connected to the second contact via 380 and the contact plug 330, the preliminary second insulating spacer 360 may be first formed in the second via hole VH2. Therefore, in an embodiment, because a separate process for removing the source structure 340 of a location corresponding to the contact plug 330 is not required to be performed, the manufacturing cost of the semiconductor device may be reduced.

Although embodiments according to the technical spirit of the present disclosure have been described with reference to the accompanying drawings, this is only for describing an embodiment according to the concept of the present disclosure, and the present disclosure is not limited to the above-described embodiments. In the scope of the technical spirit of the present disclosure described in the claims, various forms of substitution, modification, and change of the embodiments will be possible by those skilled in the art to which the present disclosure belongs, and these also belong to the scope of the present disclosure.

What is claimed is:

1. A semiconductor device comprising:
at least one channel structure extending through a gate structure;
a contact plug extending through a stack;
a source structure located on the gate structure to connect to the at least one channel structure, and extending onto the stack;
an interlayer insulating layer located on the source structure;
a first contact via extending through the interlayer insulating layer and connected to the source structure; and
a second contact via including a first portion having a first width within the source structure and connected to the contact plug, and a second portion having a second width different from the first width and extending through the interlayer insulating layer to connect to the first portion.

2. The semiconductor device of claim 1, wherein the first width is greater than the second width.

3. The semiconductor device of claim 2, wherein a sidewall in the source structure of the first portion includes a curved surface.

4. The semiconductor device of claim 3, wherein a sidewall of the first portion includes substantially an ellipse shape.

5. The semiconductor device of claim 1, further comprising:
a second insulating spacer surrounding a sidewall of the second contact via; and
a third insulating spacer surrounding a sidewall of the second insulating spacer.

6. The semiconductor device of claim 5, wherein the second insulating spacer is located within the interlayer insulating layer and the source structure.

7. The semiconductor device of claim 5, wherein the second insulating spacer extends between the second contact via and the contact plug.

8. The semiconductor device of claim 5, wherein the third insulating spacer is located within the interlayer insulating layer.

9. The semiconductor device of claim 1, further comprising:
a first insulating spacer surrounding a sidewall of the first contact via.

10. The semiconductor device of claim 9, wherein the first insulating spacer is located within the interlayer insulating layer.

11. The semiconductor device of claim 1, wherein the first contact via having a third width, the third width is less than the second width of the second contact via.

12. The semiconductor device of claim 1, further comprising:
a peripheral circuit;
a bonding structure located on the peripheral circuit;
a first interconnection structure connecting the peripheral circuit and the bonding structure; and
a second interconnection structure connecting the bonding structure and the contact plug.

13. The semiconductor device of claim 12, wherein the peripheral circuit includes a transistor,
the bonding structure includes first bonding pads and second bonding pads on the first bonding pads,
the first interconnection structure connects the transistor and at least one of the first bonding pads, and
the second interconnection structure connects at least one of the second bonding pads and the contact plug.

14. The semiconductor device of claim 1, wherein each of the at least one channel structure includes a channel layer, a memory layer surrounding the channel layer, and an insulating core within the channel layer.

15. The semiconductor device of claim 14, wherein the channel layer is connected to the source structure.

16. A semiconductor device comprising:
a gate structure;
a stack located at a level corresponding to the gate structure;
at least one channel structure extending through the gate structure;
a contact plug extending through the gate structure;
a source structure located on the gate structure to connect to the at least one channel structure, and extending onto the stack;
an interlayer insulating layer located on the source structure;
a first contact via extending through the interlayer insulating layer and connected to the source structure; and
a second contact via including a first portion having a first width within the source structure and connected to the contact plug, and a second portion having a second width less than the first width and extending through the interlayer insulating layer to connect to the first portion.

17. The semiconductor device of claim 16, wherein a sidewall in the source structure of the first portion includes a curved surface.

18. The semiconductor device of claim 17, wherein the sidewall of the first portion includes substantially an ellipse shape.

19. The semiconductor device of claim 16, further comprising:
a second insulating spacer surrounding a sidewall of the second contact via;
a third insulating spacer surrounding a sidewall of the second insulating spacer; and
an additional insulating spacer surrounding a sidewall of the contact plug.

20. The semiconductor device of claim 19, wherein the second insulating spacer is located within the interlayer insulating layer and the source structure,
the third insulating spacer is located within the interlayer insulating layer, and
the additional insulating spacer is located within the gate structure.

21. The semiconductor device of claim 19, wherein the second insulating spacer extends between the second contact via and the contact plug.

22. The semiconductor device of claim 1, further comprising:
a first insulating spacer surrounding a sidewall of the first contact via.

23. The semiconductor device of claim 22, wherein the first insulating spacer is located within the interlayer insulating layer.

24. The semiconductor device of claim 16, wherein the first contact via having a third width, the third width is less than the second width of the second contact via.

25. A semiconductor device comprising:
a gate structure;
a stack located at a level corresponding to the gate structure;
a source structure located on the gate structure and extending onto the stack;
a contact plug extending into the source structure through the stack;
an interlayer insulating layer located on the source structure;
a first contact via extending through the interlayer insulating layer and connected to the source structure;
a second contact via extending through the interlayer insulating layer into the source structure and connected to the contact plug;
a first insulating spacer surrounding a sidewall of the first contact via; and
a second insulating spacer surrounding a sidewall of the second contact via and extending between the second contact via and the contact plug.

26. The semiconductor device of claim 25, wherein a sidewall in the source structure of the first portion includes a curved surface and is connected to the contact plug, and
the second portion extends through the interlayer insulating layer to connect to the first portion.

27. The semiconductor device of claim 25, further comprising:
a third insulating spacer surrounding a sidewall of the second insulating spacer.

28. The semiconductor device of claim 27, wherein the second insulating spacer is located within the interlayer insulating layer and the source structure, and
the third insulating spacer is located within the interlayer insulating layer.

29. The semiconductor device of claim 25, wherein the first insulating spacer is located within the interlayer insulating layer.

30. The semiconductor device of claim 25, wherein the first contact via having a third width, the third width is less than the second width of the second contact via.

31. The semiconductor device of claim 25, further comprising:
a peripheral circuit;
a bonding structure located on the peripheral circuit;
a first interconnection structure connecting the peripheral circuit and the bonding structure; and
a second interconnection structure connecting the bonding structure and the contact plug.

32. The semiconductor device of claim 31, wherein the peripheral circuit includes a transistor,
the bonding structure includes first bonding pads and second bonding pads on the first bonding pads,
the first interconnection structure connects the transistor and at least one of the first bonding pads, and
the second interconnection structure connects at least one of the second bonding pads and the contact plug.

33. The semiconductor device of claim 25, further comprising:
at least one channel structure extending into the source structure through the gate structure.

34. The semiconductor device of claim 33, wherein each of the at least one channel structure includes a channel layer, a memory layer surrounding the channel layer, and an insulating core within the channel layer.

35. The semiconductor device of claim 34, wherein the channel layer is connected to the source structure.
